(19) United States
(12) Patent Application Publication
(10) Pub. No.: US 2020/0243739 A1
(43) Pub. Date: Jul. 30, 2020

(54) BOARD CONNECTION STRUCTURE, BOARD MOUNTING METHOD, AND MICRO-LED DISPLAY

(71) Applicant: V TECHNOLOGY CO., LTD., Yokohama-shi (JP)

(72) Inventors: Koichiro FUKAYA, Yokohama-shi (JP); Koichi KAJIYAMA, Yokohama-shi (JP)

(21) Appl. No.: 16/847,526

(22) Filed: Apr. 13, 2020

Related U.S. Application Data
(63) Continuation of application No. PCT/JP2018/038626, filed on Oct. 17, 2018.

(30) Foreign Application Priority Data
Oct. 26, 2017 (JP) 2017-206998

(51) Int. Cl. H01L 33/62; H01L 25/075

(52) U.S. Cl. CPC H01L 33/62; H01L 2933/0066; H01L 25/0753

(57) ABSTRACT

Provided is a board connection structure for mounting a micro LED 3 on a wiring board 4. A conductive elastic protrusion 7 is formed by patterning on an electrode pad 6 provided on the wiring board 4 at a position corresponding to a position of a corresponding electrode 5 of the micro LED 3. The elastic protrusion 7 is configured to electrically connect the electrode 5 and the electrode pad 6. This enables mounting of electronic components with a narrow electrode spacing.

This application is a continuation application of PCT/JP2018/038626, filed on Oct. 17, 2018.

### BACKGROUND OF THE INVENTION

### Field of the Invention

The present invention relates to board connection structures for mounting an electronic component on a wiring board, and more particularly, relates to board connection structures, board mounting methods, and micro-LED displays, enabling mounting of electronic components with narrow electrode spacing.

### Description of Related Art

In a conventional board connection structure, a light emitting element is provided on a mounting substrate on which circuits, and the like, are formed, by means of an adhesive material that is an anisotropic conductive material (for example, see WO2014/132979).

In such a conventional board connection structure, an anisotropic conductive film (hereinafter, referred to as “ACF”) obtained by mixing fine metal particles in a thermosetting resin, or an anisotropic conductive paste (ACP), is used as an adhesive for an anisotropic conductive material. Thus, the distance between the electrodes is limited by the particle size of the metal particles. At present, the distance between the electrodes cannot be less than about 8 μm to 10 μm.

Thus, it is difficult to mount, on a mounting board, a micro light emitting diode (LED) having outer dimensions of 10 μm×30 μm or less, for example. Therefore, there has been a problem in that a high-definition LED display cannot be manufactured.

### SUMMARY OF THE INVENTION

In view of this problem, an object of the present invention is therefore to provide a board connection structure, a board mounting method, and a micro-LED display, enabling mounting of an electronic component having a narrow electrode spacing.

In order to achieve the object, a board connection structure according to the present invention is a board connection structure for mounting an electronic component on a wiring board, the board connection structure including: an electrode pad provided on the wiring board at position corresponding to a position where an electrode of the electronic component is to be provided; and a conductive elastic protrusion formed on the electrode pad by patterning, and configured to electrically connect the electrode and the electrode pad.

Furthermore, a board mounting method according to the present invention is a board mounting method for mounting an electronic component on a wiring board by using the aboveboard connection structure, including the steps of:
forming a conductive elastic protrusion by patterning on an electrode pad provided on the wiring board at a position corresponding to a position where an electrode of the electronic component is to be provided;
applying a photosensitive adhesive to the wiring board, and then exposing and developing the applied adhesive, to form an adhesive layer around the electrode pad; and
positioning the electronic component on the wiring board, and then pressing the electronic component, to electrically connect the electrode of the electronic component and the electrode pad of the wiring board through the conductive elastic protrusion, and curing the adhesive layer to bond the electronic component to the wiring board.

Furthermore, a micro-LED display according to the present invention is a micro-LED display including: multiple micro LEDs arranged in a matrix form; and
a wiring board provided with electrode pads at positions corresponding to positions of electrodes of the micro LEDs,
wherein the wiring board has the aboveboard connection structure, wherein the board connection structure is a structure in which a conductive elastic protrusion is formed by patterning on each electrode pad, the elastic protrusion being configured to electrically connect the electrode and the electrode pad.

According to the present invention, since the elastic protrusion can be formed by using a photolithography process, it is possible to ensure high accuracy in position and shape. Thus, it is possible to reduce the distance between electrodes of the electronic component to half or less of the distance that can be employed when using the ACF, and it is also possible to enable mounting of the microelectronic component on the substrate. As a result, it is possible to ease the size limitation of the electronic component due to the electrode spacing. This increases the quantity of manufacture of micro LEDs per wafer, for example, resulting in reduced costs.

### BRIEF DESCRIPTION OF THE DRAWINGS

FIG. 1 is a plan view schematically showing a micro-LED display according to a first embodiment of the present invention.

FIG. 2 is an enlarged cross-sectional view of the main part of FIG. 1.

FIG. 3 is a cross-sectional view schematically showing a board connection structure according to the present invention.

FIGS. 4A to 4D are diagrams for explaining processes of a board mounting method according to the present invention.

FIGS. 5A and 5B are diagrams for explaining formation of a fluorescent layer array of the micro-LED display.

FIGS. 6A and 6B are diagrams for explaining assembly of a wiring board and the fluorescent layer array of the micro-LED display.

FIG. 7 is an enlarged cross-sectional view of the main part of a micro-LED display according to a second embodiment of the present invention.

FIG. 8 is an enlarged cross-sectional view of the main part of a micro-LED display according to a third embodiment of the present invention.

### DESCRIPTION OF PREFERRED EMBODIMENTS

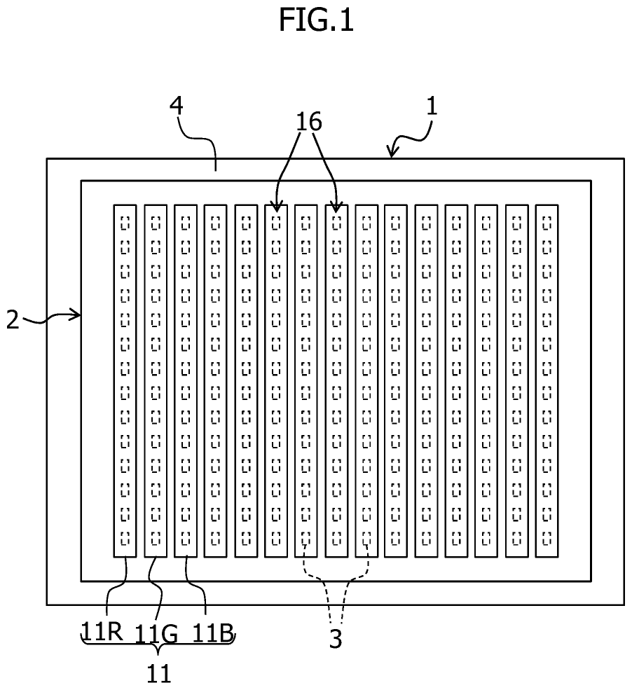

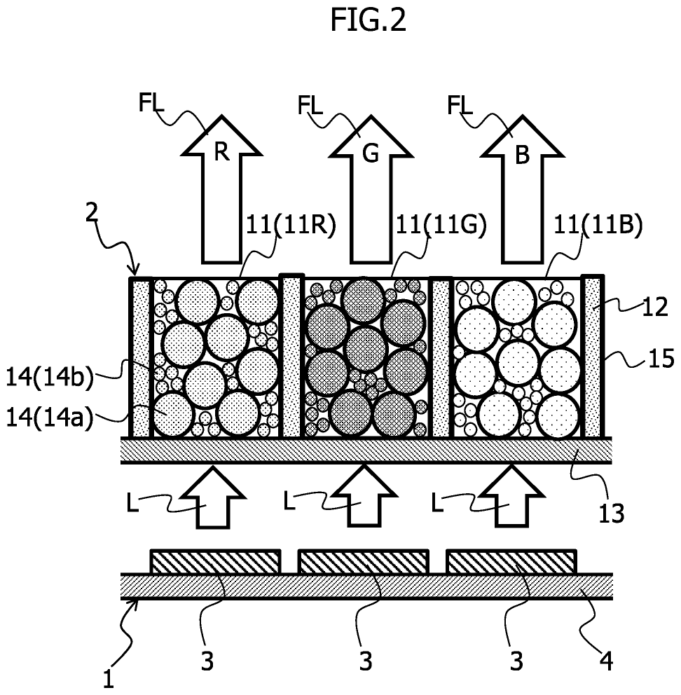

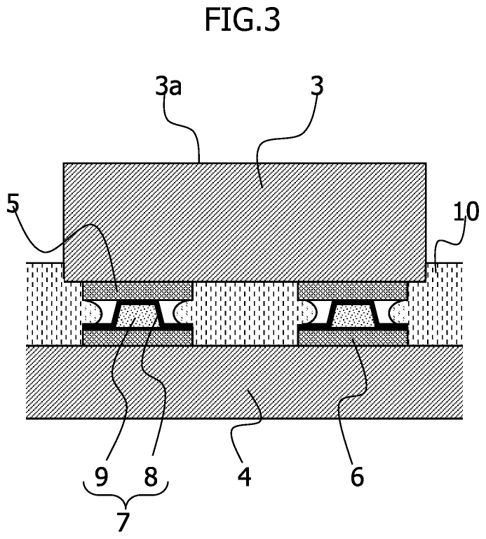

Hereinbelow, embodiments of the present invention will be described in detail with reference to the accompanying drawings. FIG. 1 is a plan view schematically showing a micro-LED display according to a first embodiment of the present invention. FIG. 2 is an enlarged cross-sectional view of the main part of FIG. 1. FIG. 3 is a cross-sectional view schematically showing a board connection structure according to the present invention. The micro-LED display displays color images, and includes an LED array substrate 1 and a fluorescent layer array 2.

The LED array substrate 1 is provided with multiple micro LEDs 3, serving as electronic components, arranged in a matrix form, as shown in FIG. 1. The LED array substrate 1 has a structure in which the multiple micro LEDs 3 are arranged on a wiring board 4 that includes wiring for supplying an image signal to each micro LED 3 from a drive circuit provided externally, and that drives the micro LEDs 3 individually to be ON and OFF to turn on and off the micro LEDs 3.

Specifically, the wiring board 4 is provided with electrode pads 6, each of which is arranged at the installation position of each micro LED 3 so as to be located at a position corresponding to a position of a corresponding electrode 5 of the micro LED 3, which is provided opposite a light outcoupling surface 3a, as shown in FIG. 3. Each electrode pad 6 is connected to an external drive circuit through wiring (not shown).

The multiple micro LEDs 3 are provided on the wiring board 4, as shown in FIG. 1. Each micro LED 3 emits light in an ultraviolet or blue wavelength band. The micro LEDs 3 are manufactured using gallium nitride (GaN) as a main material. The LED may be an LED that emits a near-ultraviolet light having a wavelength of, for example, 200 nm to 380 nm, or may be an LED that emits a blue light having a wavelength of, for example, 380 nm to 500 nm.

Specifically, as shown in FIG. 3, a micro LED 3 is configured such that an electrode 5 of the micro LED 3 and a corresponding electrode pad 6 of the wiring board 4 are electrically connected through a conductive elastic protrusion 7 formed on the electrode pad 6 by patterning.

More specifically, the elastic protrusion 7 may be a resin columnar protrusion 9 having a surface on which a conductive film 8 of superior conductivity, such as gold or aluminum, is deposited, or may be a columnar protrusion 9 made of a conductive photoresist obtained by adding conductive fine particles, such as silver, to a photoresist, or be made of a conductive photoresist containing a conductive polymer. The board connection structure of the present invention includes the electrode 5 of the micro LED 3, the electrode pad 6 of the wiring board 4, and the elastic protrusion 7. Although FIG. 3 illustrates, as an example, a case in which the columnar protrusions 9, each having the surface on which the conductive film 8 is deposited, are formed as the elastic protrusions 7, the elastic protrusions 7 may be made of a conductive photoresist.

Furthermore, as shown in FIG. 3, the micro LEDs 3 are bonded and secured to the wiring board 4 by means of an adhesive layer 10 provided around the electrode pads 6 of the wiring board 4. In this case, the adhesive layer 10 is preferably a photosensitive adhesive that is capable of being subjected to patterning by exposure and development. Alternatively, the adhesive layer 10 may be an underfill agent, or an ultraviolet-curable adhesive.

The fluorescent layer array 2 is provided above the micro LEDs 3, as shown in FIG. 2. The fluorescent layer array 2 includes multiple fluorescent layers 11, each of which performs wavelength conversion by being excited by excitation light L emitted from corresponding micro LEDs 3 and by emitting fluorescence FL of the corresponding color. The fluorescent layers 11 for red, green and blue colors are separated by partition walls 12 and are provided on a transparent substrate 13. As used herein, “upside” always refers to a side of the display surface regardless of the installation state of the micro-LED display.

Specifically, each fluorescent layer 11 is obtained by mixing and dispersing fluorescent colorants 14a having a larger particle diameter of several tens of microns and fluorescent colorants 14b having a smaller particle diameter of several tens of nanometers in a resist film. Although the fluorescent layer 11 may include only the fluorescent colorants 14a having a larger particle diameter, this may decrease the packing efficiency of the fluorescent colorants, and thus, may increase leakage of excitation light L to the display surface. On the other hand, if the fluorescent layer 11 includes only the fluorescent colorants 14b having a smaller particle diameter, there might have been a problem in that the stability, such as lightfastness, is reduced. Thus, by forming the fluorescent layer 11 to include a mixture of the fluorescent colorants 14a having a larger particle diameter and the fluorescent colorants 14b having a smaller particle diameter, as described above, it is possible to reduce leakage of excitation light L to the display surface and improve the luminous efficiency.

In this case, for the mixing ratio of fluorescent colorants 14 having different particle diameters, it is desired to set the fluorescent colorants 14a having a larger particle diameter to be 50 to 90% by volume, and to set the fluorescent colorants 14b having a smaller particle diameter to be 10 to 50% by volume. Although FIG. 1 shows a case in which the fluorescent layers 11 for red, green, and blue colors are arranged in the form of stripes, a fluorescent layer 11 may be provided above every micro LED 3 individually.

Furthermore, the partition walls 12 provided so as to surround the fluorescent layers 11 for red, green, and blue colors, separate the fluorescent layers 11 for red, green, and blue colors. Each partition wall 12 is made of a transparent resin, such as a transparent photosensitive resin. In order to increase the packing efficiency of the fluorescent colorants 14a having a larger particle diameter in each fluorescent layer 11, it is desired to use a high aspect material having a height-to-width aspect ratio of three or more, as the partition wall 12. As such a high aspect material, SU-8 3000 photoresist, manufactured by Nippon Kayaku Co., Ltd., may be used, for example.

As shown in FIG. 2, a metal film 15 is provided on the surface of each partition wall 12. This metal film 15 is provided to prevent excitation light L and fluorescence FL, which is emitted when the fluorescent layer 11 is excited by the excitation light L, from transmitting through a partition wall 12, and thus, from being mixed with fluorescence FL of the adjacent fluorescent layer 11 of another color. The metal film 15 is formed to have a thickness sufficient to block excitation light L and fluorescence FL. In this case, as the metal film 15, a thin film of aluminum, an aluminum alloy, or the like, that easily reflects excitation light L may be preferable. Thus, excitation light L transmitted through a fluorescent layer 11 to a partition wall 12 is reflected by the metal film 15, such as aluminum, inside the fluorescent layer 11, so as to make the reflected excitation light L used for light emission of the fluorescent layer 11. This results in an improved luminous efficiency of the fluorescent layer 11. Herein, the thin film deposited on the surface of the partition wall 12 is not limited to the metal film 15 that reflects excitation light L and fluorescence FL, and it may be a film that absorbs excitation light L and fluorescence FL.

Next, the manufacture of the micro-LED display thus configured will be described.

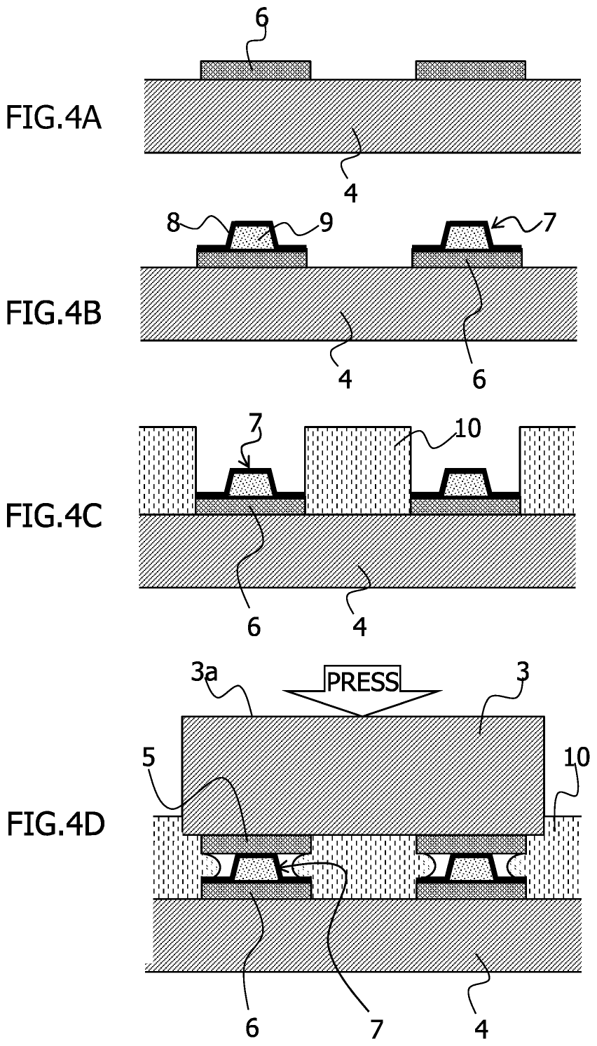

First, a board mounting method of the micro LEDs 3 on the wiring board 4 will be described with reference to FIGS. 4A to 4D.

As shown in FIG. 4A, the wiring board 4 provided with the electrode pads 6 is prepared. Each electrode pad 6 is located at a position corresponding to a position of a corresponding electrode 5 of the multiple micro LEDs 3 to be placed on the wiring board 4. This wiring board 4 can be manufactured by a known technique.

Next, referring to FIG. 4B, a resist for forming a photo spacer is applied to the entire upper surface of the wiring board 4, and then, the resist is exposed using a photomask and is developed to form a columnar protrusion 9 on each electrode pad 6 by patterning. Then, on the columnar protrusions 9 and the electrode pads 6, a conductive film 8 of superior conductivity, such as gold or aluminum, is formed, by sputtering or vapor deposition, for example, to form the elastic protrusions 7.

Specifically, before forming the conductive film 8, a resist layer is formed by photolithography on the periphery of the electrode pads 6 (i.e., except on the electrode pads 6), and after forming the conductive film 8, the resist layer is dissolved with a solution, and thus, the conductive film 8 on the resist layer is lifted off.

The elastic protrusions 7 may be columnar protrusions 9, each made of a conductive photoresist obtained by adding conductive fine particles, such as silver, to a photoresist, or a conductive photoresist containing a conductive polymer. In this case, the elastic protrusions 7 are formed by patterning as the columnar protrusions 9 on the electrode pads 6, by applying a conductive photoresist to the entire upper surface of the wiring board 4 to a predetermined thickness, exposing the photoresist using a photomask, and developing the photoresist.

Since the elastic protrusions 7 can thus be formed by applying such a photolithography process, it is possible to secure high precision in position and shape, and it is also possible to easily form the elastic protrusions 7 even when the distance between the electrodes 5 of the micro LEDs 3 is less than about 10 μm. Therefore, it is possible to manufacture a high-definition micro-LED display.

Furthermore, since the elastic protrusion 7 is configured to contact a corresponding electrode 5 of the micro LED 3 while being elastically deformed by pressing of the micro LED 3, it is possible to reliably bring each electrode 5 of multiple micros LED 3 into contact with the elastic protrusions 7 even when the multiple micro LEDs 3 are simultaneously pressed as described below. Therefore, it is possible to improve the production yield of the micro-LED display.

Next, referring to FIG. 4C, a photosensitive adhesive is applied to the entire upper surface of the wiring board 4, and then, the adhesive is exposed using a photomask and is developed to remove the photosensitive adhesive applied to the electrode pads 6, so as to form an adhesive layer 10 by patterning. In this case, the thickness of the applied photosensitive adhesive is set to be greater than a height dimension of the sum of the height of the electrode pad 6 of the wiring board 4 and the height of the elastic protrusion 7.

Subsequently, referring to FIG. 4D, micro LEDs 3 are positioned so that each electrode 5 of the micro LEDs 3 is arranged above a corresponding electrode pad 6 provided on the wiring board 4, and then, the light outcoupling surface 3a of each micro LED 3 is pressed such that the electrode 5 and the electrode pad 6 are electrically connected through the conductive elastic protrusion 7. Then, the adhesive layer 10 is cured to bond the micro LED 3 to the wiring board 4. In this way, the mounting of the micro LEDs 3 on the wiring board 4 is completed, and the LED array board 1 is thus manufactured. Here, the adhesive layer 10 may be made of a thermosetting adhesive or an ultraviolet-curable adhesive.

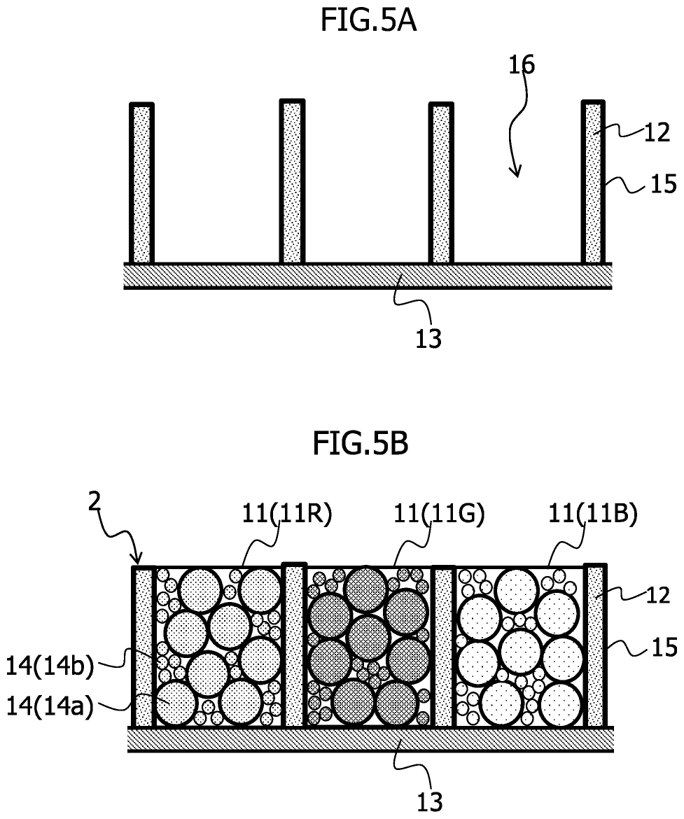

Next, formation of the fluorescent layer array 2 will be described with reference to FIGS. 5A and 5B.

First, referring to FIG. 5A, a transparent photosensitive resin for forming the partition walls 12 is applied to a transparent substrate 13 that transmits therethrough at least light in a near ultraviolet or blue wavelength band and is made of, for example, a glass substrate or a plastic substrate, such as an acrylic resin. Then, the resin is exposed using a photomask and is developed to form the transparent partition walls 12 defining stripes of openings 16, as shown in FIG. 1, for example, at positions where the fluorescent layers 11 are to be formed, each partition wall 12 having a height-to-width aspect ratio of three or more, and having a height of about 20 μm or more. In this case, it may be preferable to use a photosensitive resin of a high aspect material, such as SU-8 3000, manufactured by Nippon Kayaku Co., Ltd., for example.

Next, a metal film 15 of, for example, aluminum or an aluminum alloy, is formed to a predetermined thickness on the partition walls 12 formed on the transparent substrate 13 by applying a known deposition technique, such as sputtering. After the film formation, the metal film 15 deposited on the transparent substrate 13 at the bottom of each opening 16 surrounded by the partition walls 12 is removed by laser irradiation.

Alternatively, a resist or the like may be applied, to a thickness of several μm by inkjet, for example, to the surface of the transparent substrate 13 at the bottom of each opening 16 before the film formation, and then, after forming the metal film 15, the resist and the metal film 15 on the resist may be lifted off and removed. In this case, it will be apparent to one skilled in the art that a chemical solution that does not destroy the resin of the partition walls 12 is selected as a resist solution used for the liftoff.

Next, referring to FIG. 5B, a resist containing, for example, a red fluorescent colorant 14 is applied, by inkjet, for example, to multiple openings 16 for red color, for example, which are surrounded by the partition walls 12. The resist is then cured by ultraviolet irradiation to form red fluorescent layers 11R. Alternatively, the resist containing the red fluorescent colorant 14 may be applied to cover the transparent substrate 13, and then, the resist may be exposed using a photomask and be developed to form red fluorescent layers 11R in multiple openings 16 for red color. In this case, the resist is obtained by mixing and dispersing a fluorescent colorant 14a having a larger particle diameter and a fluorescent colorant 14b having a smaller particle diameter, and the mixing ratio thereof is such that the fluorescent colorant 14a having a larger particle diameter is 50 to 90% by volume and the fluorescent colorant 14b having a smaller particle diameter is 10 to 50% by volume.

Similarly, a resist containing, for example, a green fluorescent colorant 14 is applied, by inkjet, for example, to multiple openings 16 for green color, for example, which are surrounded by the partition walls 12. The resist is then cured by ultraviolet irradiation to form green fluorescent layers 11G. Alternatively, the resist containing the green fluorescent colorant 14, applied to the entire upper surface of the transparent substrate 13 in a similar manner as described above, may be exposed using a photomask and developed, to form green fluorescent layers 11G in multiple openings 16 for green color.

Furthermore, in a similar manner, a resist containing, for example, a blue fluorescent colorant 14 is applied, by inkjet, for example, to multiple openings 16 for blue color, for example, which are surrounded by the partition walls 12. The resist is then cured by ultraviolet irradiation to form blue fluorescent layers 11B. Also in this case, the resist containing the blue fluorescent colorant 14 applied to the entire upper surface of the transparent substrate 13 may be exposed using a photomask and be developed to form blue fluorescent layers 11B in multiple openings 16 for blue color.

In this case, it may be preferable to provide an antireflection film for preventing external light from being reflected on the display surface of the fluorescent layer array 2. Furthermore, it may be preferable to apply a black paint to the metal film 15 on the display surface side of the partition walls 12. By taking these measures, it is possible to reduce the reflection of external light at the display surface, resulting in the improved contrast.

Subsequently, an assembly process of the LED array substrate 1 and the fluorescent layer array 2 is performed.

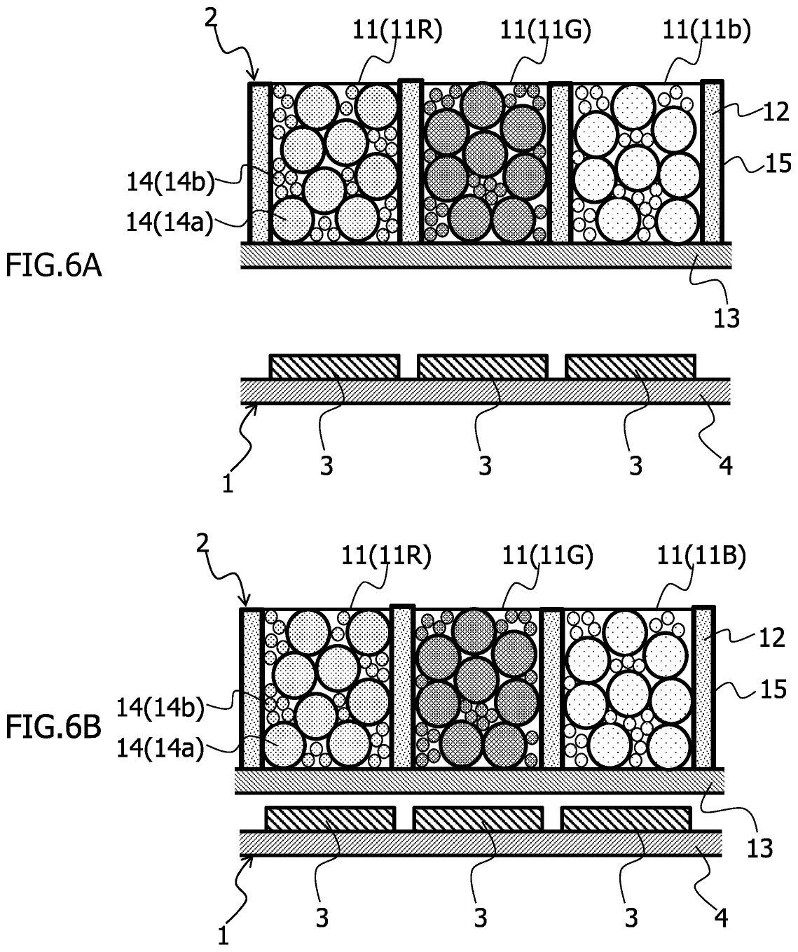

First, as shown in FIG. 6A, the fluorescent layer array 2 is positioned above the LED array substrate 1. Specifically, the fluorescent layers 11 for red, green, and blue colors of the fluorescent layer array 2 are aligned with corresponding LEDs 3 placed on the LED array substrate 1 by using alignment marks formed on the LED array substrate 1 and alignment marks formed on the fluorescent layer array 2.

When the alignment of the LED array substrate 1 and the fluorescent layer array 2 is completed, the LED array substrate 1 and the fluorescent layer array 2 are joined by an adhesive (not shown) to form a micro-LED display, as shown in FIG. 6B.

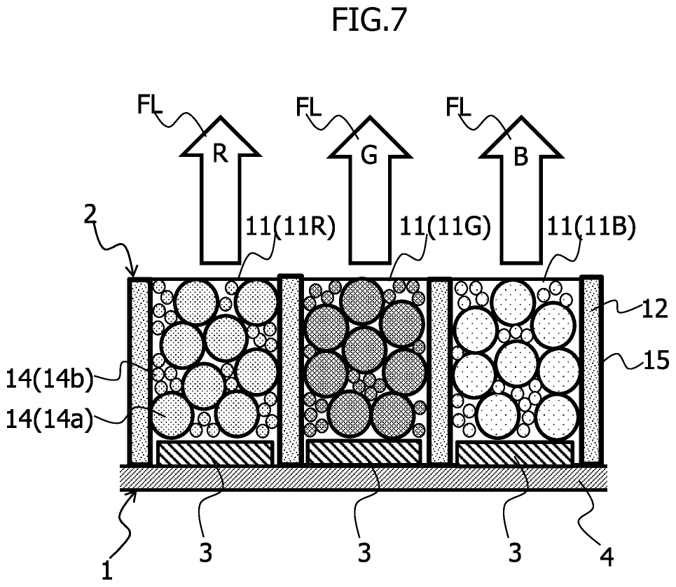

FIG. 7 is an enlarged cross-sectional view of the main part of the micro-LED display according to a second embodiment of the present invention.

The second embodiment differs from the first embodiment in that the fluorescent layers 11 for red, green and blue colors, and the partition walls 12 are placed directly on the LED array substrate 1.

Next, the manufacture of the micro-LED display according to the second embodiment configured as described above will be described.

First, an LED array substrate 1 is manufactured in a manner similar to that in the first embodiment; multiple micro LEDs 3 emitting light in a near ultraviolet or blue wavelength band are arranged at predetermined positions on a wiring board 4 provided with wiring for driving the multiple micro LEDs 3, and each electrode 5 of the multiple LEDs 3 is electrically connected to a corresponding electrode pad 6 formed on the wiring board 4 through a conductive elastic protrusion 7.

Next, a transparent photosensitive resin for forming partition walls 12 is applied to the LED array substrate 1, and then, the resin is exposed using a photomask and is developed to form the transparent partition walls 12 defining stripes of openings 16, as shown in FIG. 1, for example, at positions where the micro LEDs 3 for red, green and blue colors are to be formed on the LED array substrate 1, each partition wall 12 having a height-to-width aspect ratio of three or more, and having a height of about 20 μm or more.

Next, a metal film 15 of, for example, aluminum or an aluminum alloy, is formed with a predetermined thickness on the partition walls 12 formed on the LED array substrate 1 by applying a known deposition technique, such as sputtering. After the film formation, the metal film 15 deposited on each micro LED 3 at the bottom of each opening 16 surrounded by the partition walls 12 is removed.

In this case, a resist or the like may be preferably applied to a thickness of several μm by inkjet, for example, to each micro LED 3 at the bottom of each opening 16 before the film formation, and then, after forming the metal film 15, the resist and the metal film 15 on the resist may be preferably lifted off and removed. It will be apparent to one skilled in the art that a chemical solution that does not destroy the resin of the partition walls 12 is selected as a resist solution used for the liftoff.

Next, a resist containing, for example, a red fluorescent colorant 14 is applied, by inkjet, for example, to micro LEDs 3, each having a light outcoupling surface exposed, in multiple openings 16 for red color, for example, which are surrounded by the partition walls 12. The resist is then cured by ultraviolet irradiation to form red fluorescent layers 11R. Alternatively, the resist containing the red fluorescent colorant 14 may be applied to cover the LED array substrate 1, and then, the resist may be exposed using a photomask and be developed to form red fluorescent layers 11R directly on micro LEDs 3, each having a light outcoupling surface exposed, in multiple openings 16 for red color. In this case, the resist is obtained by mixing and dispersing a fluorescent colorant 14a having a larger particle diameter and a fluorescent colorant 14b having a smaller particle diameter, and the mixing ratio thereof is such that the fluorescent colorant 14a having a larger particle diameter is 50 to 90% by volume and the fluorescent colorant 14b having a smaller particle diameter is 10 to 50% by volume.

Similarly, a resist containing, for example, a green fluorescent colorant 14 is applied, by inkjet, for example, to micro LEDs 3, each having a light outcoupling surface exposed, in multiple openings 16 for green color, for example, which are surrounded by the partition walls 12. The resist is then cured by ultraviolet irradiation to form green fluorescent layers 11G. Alternatively, the resist containing the green fluorescent colorant 14 applied to the entire upper surface of the LED array substrate 1 in a similar manner as described above, may be exposed using a photomask and developed, to form green fluorescent layers 11G directly on micro LEDs 3, each having a light outcoupling surface exposed, in multiple openings 16 for green color.

Furthermore, in a similar manner, a resist containing, for example, a blue fluorescent colorant 14 is applied, by inkjet, for example, to multiple openings 16 for blue color, for example, which are surrounded by the partition walls 12. The resist is then cured by ultraviolet irradiation to form blue fluorescent layers 11B. Also in this case, the resist containing the blue fluorescent colorant 14, applied to the entire upper surface of the LED array substrate 1 in a similar manner as described above, may be exposed using a photomask and be developed to form blue fluorescent layers 11B directly on micro LEDs, each having a light outcoupling surface exposed, in multiple openings 16 for blue color.

According to the second embodiment, in addition to the advantageous effects achieved by the first embodiment, it is possible to further reduce leakage of excitation light L emitted from the micro LEDs 3 to the adjacent fluorescent layers 11 as compared with the first embodiment, since the fluorescent layers 11 and the partition walls 12 are provided directly on the LED array substrate 1. Therefore, it is possible to further improve the luminous efficiency of each fluorescent layer 11.

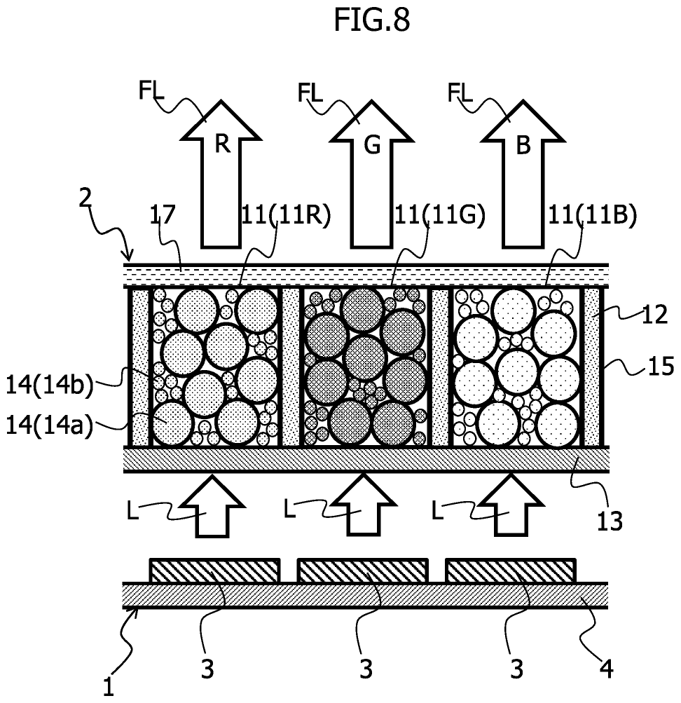

FIG. 8 is an enlarged cross-sectional view of the main part of the micro-LED display according to a third embodiment of the present invention.

The third embodiment is different from the first embodiment in that there is provided an excitation light blocking layer 17 that covers the fluorescent layers 11 for red, green and blue colors, and the partition walls 12, to block excitation light L. This excitation light blocking layer 17 selectively reflects or absorbs light in the same wavelength band as the excitation light L, contained in external light, such as sunlight, to prevent the fluorescent layers 11 from being excited by such light and from emitting light, so as to improve color reproduction.

Specifically, when the excitation light L is ultraviolet light, the excitation light blocking layer 17 is provided so as to cover the fluorescent layers 11 for red, green and blue colors, and the partition walls 12, as shown in FIG. 8. In a case in which the excitation light L is light in the blue wavelength band, it may be preferable to provide the excitation light blocking layer 17 so as to cover fluorescent layers 11 except for the blue fluorescent layers 11B, and the partition walls 12.

Although FIG. 8 shows a case in which the excitation light blocking layer 17 is applied to the first embodiment as an example, the excitation light blocking layer 17 may also be applied to the second embodiment.

According to the third embodiment, in addition to the advantageous effects achieved by the first and second embodiments, it is possible to prevent external light from reaching the fluorescent layers 11 since the excitation light blocking layer 17 is provided on the fluorescent layers 11. Therefore, it is possible to suppress the problem of degraded color reproduction caused by excitation and light emission of the fluorescent layers 11 due to external light. Furthermore, since excitation light L transmitted through the fluorescence layers 11, which is a part of the excitation light L emitted from the micro LEDs 3, is reflected or absorbed by the excitation light blocking layer 17, it is possible to prevent the transmitted excitation light from leaking to the display surface. Therefore, it is also possible to prevent the problem of degraded color reproduction caused by mixing colors of the leaked excitation light L and the fluorescence FL of the fluorescent layers 11.

In the above embodiments, although the micro-LED display is described configured so that the fluorescent layer array 2 including the fluorescent layers 11 for red, green, and blue colors, is arranged on the LED array substrate 1 provided with the multiple micro LEDs 3 that emit excitation light in the near ultraviolet or blue wavelength band, the present invention is not limited thereto, and the LED array substrate 1 may be provided with multiple micro LEDs 3 that individually emit red, green, and blue light, arranged in a matrix form. In this case, the fluorescent layer array 2 is unnecessary.

Furthermore, the micro-LED display according to the present invention may be configured so that at least one of the micro LEDs 3 for red color, the micro LEDs 3 for green color, and the micro LEDs 3 for blue color, emit excitation light in an ultraviolet or blue wavelength band, and corresponding fluorescent layers 11 that perform wavelength conversion by the excitation light to emit fluorescence with the wavelength of the corresponding color are provided. In this case, the micro LEDs 3 other than the micro LEDs 3 that emits the excitation light, emit light in the wavelength bands of the corresponding colors without requiring the fluorescent layers 11.

Furthermore, although the electronic components are the micro LEDs 3 in the above description, the present invention is not limited thereto, and the electronic component may be semiconductor components or other microelectronic components.

It should be noted that the entire contents of Japanese Patent Application No. 2017-206998, filed on Oct. 26, 2017, on which convention priority is claimed, is incorporated herein by reference.

It should also be understood that many modifications and variations of the described embodiments of the invention will be apparent to one of ordinary skill in the art, without departing from the spirit and scope of the present invention as claimed in the appended claims.

What is claimed is:

1. A board connection structure for mounting an electronic component on a wiring board, comprising:
an electrode pad provided on the wiring board at a position corresponding to a position where an electrode of the electronic component is to be provided; and
a conductive elastic protrusion formed on the electrode pad by patterning, and configured to electrically connect the electrode and the electrode pad.

2. The board connection structure according to claim 1, wherein the elastic protrusion is a resin columnar protrusion having a surface on which a conductive film is deposited, or a columnar protrusion made of a conductive photoresist.

3. The board connection structure according to claim 1, wherein the electronic component is bonded to the wiring board by an adhesive layer provided around the electrode pad.

4. The board connection structure according to claim 3, wherein the adhesive layer is a photosensitive adhesive that is capable of being subjected to patterning by exposure and development.

5. The board connection structure according to claim 1, wherein the electronic component is a micro light emitting diode (LED).

6. A board mounting method for mounting an electronic component on a wiring board by using the board connection structure according to claim 1, comprising the steps of:
forming a conductive elastic protrusion by patterning on an electrode pad provided on the wiring board at a position corresponding to a position where an electrode of the electronic component is to be provided;
applying a photosensitive adhesive to the wiring board, and then exposing and developing the applied adhesive, to form an adhesive layer around the electrode pad; and
positioning the electronic component on the wiring board, and then pressing the electronic component, to electrically connect the electrode of the electronic component and the electrode pad of the wiring board through the conductive elastic protrusion, and curing the adhesive layer to bond the electronic component to the wiring board.

7. The board mounting method according to claim 6, wherein the elastic protrusion is a resin columnar protrusion having a surface on which a conductive film is deposited, and electrically connecting the electrode of the electronic component and the electrode pad of the wiring board through the conductive film, or is a columnar protrusion made of a conductive photoresist.

8. The board mounting method according to claim 6, wherein the electronic component is a micro LED.

9. A micro-LED display comprising:
multiple micro LEDs arranged in a matrix form; and
a wiring board provided with electrode pads at positions corresponding to positions of electrodes of the micro LEDs,
wherein the wiring board has the board connection structure according to claim 1, wherein the board connection structure is a structure in which a conductive elastic protrusion is formed by patterning on each electrode pad, the elastic protrusion being configured to electrically connect an electrode and an electrode pad.
